(19) United States
(12) Patent Application Publication
(10) Pub. No.: US 2025/0022693 A1
(43) Pub. Date: Jan. 16, 2025

(54) ELECTROSTATIC CHUCKS AND SUBSTRATE PROCESSING APPARATUS INCLUDING THE SAME

(71) Applicant: SAMSUNG ELECTRONICS CO., LTD., Suwon-si (KR)

(72) Inventors: Iksu BYUN, Suwon-si (KR); Songyun KANG, Suwon-si (KR); Youngrok KWON, Suwon-si (KR)

(21) Appl. No.: 18/428,510

(22) Filed: Jan. 31, 2024

(30) Foreign Application Priority Data
Jul. 10, 2023 (KR) 10-2023-0089380

(51) Int. Cl. H01J 37/32; H01L 21/683

(52) U.S. Cl. CPC H01J 37/32724; H01L 21/6833; H01J 2237/2007; H01J 2237/327

(57) ABSTRACT

An electrostatic chuck may include a body, a body; an internal electrode in the body, wherein the internal electrode is configured to generate an electrostatic force when a voltage is applied to the internal electrode; and a coating layer on an outer surface of the body, wherein the coating layer comprises a film forming material including a silicon-containing material.

### CROSS-REFERENCE TO RELATED APPLICATION

This application claims priority to and the benefit of Korean Patent Application No. 10-2023-0089380 filed in the Korean Intellectual Property Office on Jul. 10, 2023, the entire contents of which is incorporated herein by reference.

### BACKGROUND OF THE INVENTION

The present disclosure relates to electrostatic chucks and substrate processing apparatus including the same.

Substrates that are used to fabricate semiconductors may be processed in supported states (e.g., states in which substrates are supported by structures, devices, and/or apparatus). Electrostatic chucks may be used to support substrates. An electrostatic chuck may include electrodes therein. When DC power is applied to the electrodes of the electrostatic chuck, an electrostatic force may be generated between the electrostatic chuck and a substrate positioned on a surface (e.g., an upper surface) of the electrostatic chuck. And the electrostatic force may cause the substrate to be suction-fixed (adsorbed) to the electrostatic chuck.

### SUMMARY OF THE INVENTION

The present disclosure is to provide an electrostatic chuck and a substrate processing apparatus including the same capable of stably suction-fixing (adsorbing) substrates.

However, the objective of the present disclosure is not limited to the aforementioned one, and may be extended in various ways within the scope of the present disclosure.

According to some embodiments, an electrostatic chuck may include a body; an internal electrode in the body, wherein the internal electrode is configured to generate an electrostatic force when a voltage is applied to the internal electrode; and a coating layer on an outer surface of the body, wherein the coating layer comprises a film forming material including a silicon-containing material.

According to some embodiments, an electrostatic chuck may include a body; an internal electrode in the body, wherein the internal electrode is configured to generate an electrostatic force when a first voltage is applied to the internal electrode; a heating member in the body, wherein the heating member is configured to generate heat through resistance heating when a second voltage is applied to the heating member; and a coating layer on an outer surface of the body, wherein an outer region of the body includes pyrolytic boron nitride (pBN), wherein the coating layer comprises a film forming material that includes a silicon-containing material, wherein the silicon-containing material has a coefficient of thermal expansion of 1 (10−6/K) to 4 (10−6/K).

According to some embodiments, a substrate processing apparatus may include a chamber; and an electrostatic chuck in the chamber, wherein the electrostatic chuck is configured to adsorb a substrate, the electrostatic chuck comprises: a body; an internal electrode in the body, wherein the internal electrode is configured to generate an electrostatic force when a first voltage is applied to the internal electrode; a heating member in the body, wherein the heating member is configured to generate heat through resistance heating when a second voltage is applied to the heating member; and a coating layer on an outer surface of the body, wherein an outer region of the body includes pyrolytic boron nitride, wherein the coating layer comprises a film forming material that includes a silicon-containing material, and wherein the silicon-containing material has a coefficient of thermal expansion of 1 (10−6/K) to 4 (10−6/K).

According to embodiments, an electrostatic chuck and a substrate processing apparatus including the same capable of stably suction-fixing (adsorbing) substrates may be provided.

### BRIEF DESCRIPTION OF THE DRAWINGS

FIG. 1 is a drawing showing an electrostatic chuck according to some embodiments.

FIG. 2 to FIG. 6 are drawings showing a manufacturing process of an electrostatic chuck according to some embodiments.

FIG. 7 is a simulation result of wear characteristics.

FIG. 8 is a drawing showing a substrate processing apparatus including an electrostatic chuck of FIG. 1 according to some embodiments.

FIG. 9 is a drawing showing a substrate processing apparatus including an electrostatic chuck of FIG. 1 according to some embodiments.

FIG. 10 is a drawing showing a substrate processing apparatus including an electrostatic chuck of FIG. 1 according to some embodiments.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

In order to clearly describe the present invention, parts or portions that are irrelevant to the description may be omitted, and identical or similar constituent elements throughout the specification may be denoted by the same reference numerals unless clearly stated otherwise.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

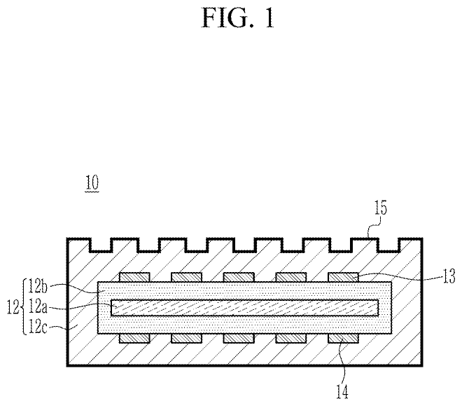

FIG. 1 is a drawing showing an electrostatic chuck according to some embodiments.

Referring to FIG. 1, according to some embodiment, an electrostatic chuck 10 may include a body 12, an internal electrode 13, a heating member 14 and a coating layer 15.

The body 12 may be provided as a plate structure having a preset thickness. An outer circumference of the body 12 may be circular. For example, the body 12 may be in a disk shape, but is not limited thereto. An outer region of the body 12 (e.g., an outer body 12c which will be described below) may include, for example, a dielectric material. The body 12 may include a core member 12a, an inner body 12b, and the outer body 12c.

The core member 12a may be positioned at an inner central region of the body 12. The core member 12a may be provided as a plate structure having a preset thickness. The core member 12a may include, for example, graphite.

The inner body 12b may be positioned outside the core member 12a. For example, the core member 12a may be disposed inside of the inner body 12b. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device. The inner body 12b may be provided as a structure extending around (e.g., surrounding) an outer surface of the core member 12a. For example, the inner body 12b may extend around (e.g., surround) the core member 12a. The inner body 12b may include, for example, a dielectric material. For example, the inner body 12b may include pyrolytic boron nitride (pBN), but is not limited thereto.

The outer body 12c may be positioned outside the inner body 12b. For example, the inner body 12b may be disposed inside of the outer body 12c. The outer body 12c may be provided as a structure extending around (e.g., surrounding) an outer surface of the inner body 12b. For example, the outer body 12c may extend around (e.g., surround) the inner body 12b. The outer body 12c may include, for example, a dielectric material. The outer body 12c may include a same material as the inner body 12b, but is not limited thereto. For example, the outer body 12c may include pBN).

The internal electrode 13 may be positioned inside the body 12. The internal electrode 13 may generate an electrostatic force to generate a force to suction-fix (adsorb) a substrate, when a voltage is applied to the internal electrode 13. The substrate herein may refer to, for example, a semiconductor wafer to be processed. The internal electrode 13 may include, for example, a conductive material. For example, the internal electrode 13 may include graphite, but is not limited thereto. The internal electrode 13 may include pyrolytic graphite. The internal electrode 13 may be positioned between the inner body 12b and the outer body 12c. The internal electrode 13 may be positioned on an upper side (e.g., an upper surface) of the inner body 12b.

The heating member 14 may be positioned inside the body 12. When a voltage is applied to the heating member 14, the heating member 14 may generate heat through resistance heating, to heat the body 12 and the suction-fixed (adsorbed) substrate. The heating member 14 may include, for example, a conductive material. For example, the heating member 14 may include graphite, but is not limited thereto. The heating member 14 may include pyrolytic graphite. The heating member 14 may be positioned between the inner body 12b and the outer body 12c. The heating member 14 may be positioned on a lower side (e.g., a lower surface) of the inner body 12b. For example, the internal electrode 13 and the heating member 14 may be disposed on opposite sides (e.g., opposite surfaces) with respect to the core member 12a and/or the inner body 12b.

The coating layer 15 may be positioned on an outer surface of the body 12. Herein, the outer surface and an outer region of the body 12 may refer to an outer surface and a region of the outer body 12c, respectively. For example, the coating layer 15 may extend around (e.g., surround) the body 12 (e.g., outer body 12c). The coating layer 15 may be formed over an entire outer surface of the body 12. In some embodiments, the coating layer 15 may be formed on an upper region of the body 12 to which the substrate is suction-fixed (adsorbed).

The coating layer 15 may have a coefficient of thermal expansion corresponding to that of the outer region (e.g., the outer surface) of the body 12 (e.g., a coefficient of thermal expansion of the outer body 12c). The coefficient of thermal expansion of the coating layer 15 may be 50% of the lower limit value to 150% of the upper limit value of the coefficient of thermal expansion of the outer region (e.g., the outer surface) of the body 12. For example, the outer region (e.g., the outer surface) of the body 12 may include pBN and may have a coefficient of thermal expansion of 2 (10⁻⁶/K) to 3 (10⁻⁶/K). Corresponding to the above, the coating layer 15 may have a coefficient of thermal expansion of 1 (10⁻⁶/K) to 4 (10⁻⁶/K).

In some embodiments, the coating layer 15 may have a thickness of 1 micrometer (μm) to 2 mm. For example, the thickness of the coating layer 15 may be 10 μm to 200 μm.

The hardness of the coating layer 15 may be provided greater than the hardness of the outer region of the body 12. Accordingly, the hardness of the outer region of an electrostatic chuck 10 may be increased.

The coating layer 15 may be formed of a film forming material. The film forming material may include, for example, a silicon-containing material. The silicon-containing material may include, for example, silicon (Si), and/or a silicon compound.

The silicon compound may include, for example, silicon oxide, silicon nitride, and/or silicon carbide. In some embodiments, the silicon compound may include silicon and at least one element selected from among nitrogen, oxygen, and carbon. The silicon compound may include, for example, silicon nitride (SxNy), silicon oxynitride (SiNxOy), silica (SiO₂), silicon oxycarbide (SiOxCy), silicon oxycarbonitride (SiOCN), silicon carbide (SiC), and/or the like.

Table 1 shows the properties of pBN and examples embodiments of the silicon-containing materials.

TABLE 1

| | pBN | Si | SixNy | SiNxOy |
|---|---|---|---|---|
| Coefficient of thermal | 2-3 | 2.6 | 2.4-2.9 | 2.9 |
| expansion (10⁻⁶/K) | | | | |
| Thermal conductivity | 10-60 | 149 | 23-54 | 1.5-54 |
| (W/m · K) | | | | |
| Knoop hardness | 0.1 | 6 | 14 | 9.5-14 |
| (GPa) | | | | |
| Density (g/cm³) | 2.1 | 2.33 | 3.2 | 2.81 |
| Flexural Strength | 243 | — | 580-790 | — |
| (MPa) | | | | |
| Bulk modulus (GPa) | 36.5 | — | 290 | 36-290 |
| Volume Resistivity | 3 × 10\hat{ }7 | 6.4 × 10\hat{ }2 | 10\hat{ } 10-14 | 10\hat{ }14-17 |
| (Ω · cm) | | | | |
| Crystal Structure | Hexagonal | Cubic | Hexagonal | Amorphous |

TABLE 2

| | SiOx | SiOxCy | SiOCN | SiC |
|---|---|---|---|---|
| Coefficient of thermal | 0.75 | 1.8-3.2 | 3.2 | 4 |
| expansion (10⁻⁶/K) | | | | |
| Thermal conductivity | 1.5 | 1.5 | — | 300 |
| (W/m · K) | | | | |
| Knoop hardness (GPa) | 9.5 | 4-7.4 | 4-12 | 17-34 |
| Density (g/cm³) | 2.65 | 1.95 | 3.05 | 3.21 |
| Flexural Strength | — | — | 350 | — |
| (MPa) | | | | |
| Bulk modulus (GPa) | 36.8 | 20-60 | — | — |
| Volume Resistivity | <10\hat{ }17 | 10\hat{ }5 | 10\hat{ }3-5 | >10\hat{ }5 |
| (Ω · cm) | | | | |
| Crystal Structure | Amorphous | Amorphous | Amorphous | Cubic |

Referring to Table 1 and Table 2, the silicon-containing material may have a higher (greater) hardness (e.g., a higher/greater Knoop hardness) compared to pBN. Accordingly, when the coating layer 15 is formed on the outer surface (e.g., the outer circumference) of the body 12 by using the silicon-containing material, the hardness of the outer surface (e.g., the outer circumference) of the electrostatic chuck 10 (e.g., the body 12) may be improved (e.g., increased).

In some embodiment, pBN used as a material for the outer region of the body 12 may have high (higher/greater) thermal conductivity. Accordingly, the electrostatic chuck 10 may rapidly control and uniformly distribute temperature on (acrooss) the surfaces thereof. In some embodiments, pBN may have a low (lower) coefficient of thermal expansion, allowing the electrostatic chuck 10 to stably suction-fix (adsorb) the substrate.

Friction may occur during the process that the electrostatic chuck 10 adsorbs a substrate. The temperature of the electrostatic chuck 10 may change during processing of the substrate. Accordingly, during heating or cooling, friction may occur between the adsorbed substrate and a (an outer) surface of the electrostatic chuck 10 with which the adsorbed substrate is in contact, due to the difference between the coefficients of thermal expansion of the adsorbed substrate and the electrostatic chuck 10. In some embodiments, pBN (e.g., pBN in the body 12) may have a lower hardness (e.g., a lower hardness than that of the coating layer 15 or the silicon-containing materials in the coating layer 15), so the degree of wear due to friction may be higher (e.g., higher/greater than the coating layer 15 or the silicon-containing materials in the coating layer 15). The wear of the body 12 (without the coating layer 15) may shorten the lifetime of the electrostatic chuck 10, and particles generated by such wear may become a source of contamination of the (adsorbed) substrate. On the other hand, when the coating layer 15, including the silicon-containing material, is formed on the body 12 (e.g., on the outer body 12c), the wear of the electrostatic chuck 10 may be greatly reduced due to improved hardness.

In some embodiments, the silicon-containing material may have a higher density than pBN. Silicon nitride and silicon oxycarbonitride may have higher flexural strength than pBN. Silicon nitride, silicon oxynitride, and silica may have a higher bulk modulus than pBN. Accordingly, when the coating layer 15 is formed on the outer surface of the body 12 by using a silicon-containing material, various physical characteristics of the outer surface of the electrostatic chuck 10 may be improved.

In some embodiments, the silicon-containing material may have a coefficient of thermal expansion in a range similar to that of pBN. Particularly, silicon, silicon nitride (SxNy), and silicon oxynitride (SiNxOy) may have a high degree of similarity in the coefficient of thermal expansion to that of pBN. When the coefficients of thermal expansion of the outer region of the body 12 and the coating layer 15 have a high degree of similarity, thermal stress generated between the outer region of the body 12 and the coating layer 15 may be reduced. That is, when the outer region of the body 12 and the coating layer 15 have a high degree of similarity in the coefficients of thermal expansion, the bonding state between the body 12 and the coating layer 15 may be thermally stabilized.

In some embodiments, when the substrate is a silicon wafer (e.g., when the substrate includes silicon), the silicon-containing material (in the coating layer 15) may have a high (higher) degree of similarity in the coefficient of thermal expansion with the substrate. Accordingly, when the electrostatic chuck 10 (with the coating layer 15) is heated or cooled while having adsorbed the substrate thereon, friction between the electrostatic chuck 10 and the substrate may be reduced.

Silicon, silicon nitride, and silicon carbide may have excellent thermal conductivity. Accordingly, when the coating layer 15 includes, for example, silicon, silicon nitride, and/or silicon carbide, heat transfer efficiency between the electrostatic chuck 10 and the substrate may be improved.

The silicon-containing materials (in the coating layer 15) may have high (higher) volume resistivity. Particularly, silicon nitride, silicon oxynitride, and silica may have a higher volume resistivity than pBN. Accordingly, when the coating layer 15 including these materials, electrical stability of the electrostatic chuck 10 may be improved. Accordingly, the electrostatic chuck 10 may be stably used during an ion implantation process and a plasma process for the substrate.

In some embodiments, silicon nitride may have a hexagonal crystal structure, the same as the pBN. Accordingly, when the coating layer 15 includes silicon nitride, the coating layer 15 may be (more) stably bonded to the outer surface of the body 12.

The surface hardness of the electrostatic chuck 10 according to the present embodiment may be significantly improved in mechanical properties. Accordingly, the lifetime of the electrostatic chuck 10 may be increased, and generation of particles (e.g., sources of contamination of the substrate) due to friction during the use of the electrostatic chuck 10 may be reduced.

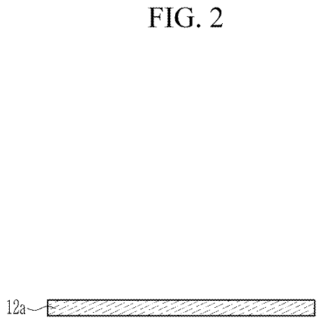

FIG. 2 to FIG. 6 are drawings showing a manufacturing process of an electrostatic chuck according to some embodiments.

Hereinafter, a manufacturing method of the electrostatic chuck 10 will be described with reference to FIG. 2 to FIG. 6.

Referring to FIG. 2, the core member 12a may be provided. The core member 12a may include, for example, graphite. The core member 12a may be made by performing shape processing to a raw material (e.g., graphite). The shape processing may be performed by a method such as cutting, such that the raw material becomes the core member 12a in a desired shape. After the shape processing, a cleaning process and a drying process may be performed on the core member 12a. The cleaning process may be performed by a method such as ultrasonic cleaning. The drying process may be performed by exposing the core member 12a to a temperature (e.g., temperature environment) higher than the room temperature. For example, the drying process may be performed by exposing the electrostatic chuck 10 (e.g., the core member 12a) to an environment of 100° C. to 110° C. for 50 minutes to 70 minutes.

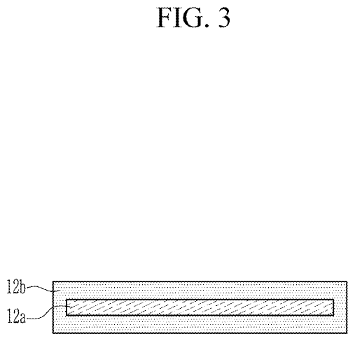

Referring to FIG. 3, the inner body 12b may be formed on the core member 12a. The inner body 12b may be formed through a deposition process. Material of the inner body 12b may include pBN. Deposition of the inner body 12b may be performed by chemical vapor deposition (CVD) using a boron precursor. The deposition process may be performed in a process environment in which carbon components are removed. Boron may have a similar lattice constant to that of the core member 12a which includes (e.g., is) graphite. Accordingly, boron crystals may stably grow on the outer surface of the core member 12a. For example, the inner body 12b may be formed to have a thickness of 100 μm to 300 μm. After the process of forming the inner body 12b, a cleaning process and a drying process may be performed. The cleaning process may be performed by a method such as ultrasonic cleaning. The drying process may be performed by exposing the electrostatic chuck 10 (e.g., the inner body 12b and/or the core member 12a) to a temperature (environment) higher than the room temperature. For example, the drying process may be performed by exposing the electrostatic chuck 10 (e.g., the inner body 12b and/or the core member 12a) to an environment of 100° C. to 110° C. for 50 minutes to 70 minutes.

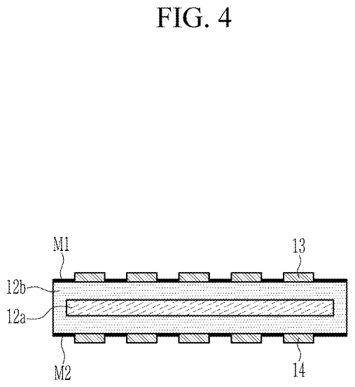

Referring to FIG. 4, the internal electrode 13 and the heating member 14 may be formed on the inner body 12b. The internal electrode 13 and the heating member 14 may be formed through a deposition process. For this purpose, masks M1 and M2 may be formed on the outer surface of the inner body 12b. The masks M1 and M2 may include a first mask M1 and a second mask M1. The masks M1 and M2 may be disposed on opposite surfaces of the inner body 12b. For example, the first mask M1 may be formed on an upper surface of the inner body 12b and provide a pattern for forming the internal electrode 13. The second mask M2 may be formed on a lower surface of the inner body 12b and provide a pattern for forming the heating member 14. Deposition of the internal electrode 13 and the heating member 14 may be performed by chemical vapor deposition (CVD). The internal electrode 13 and the heating member 14 may include, for example, pyrolytic graphite (PG), but are not limited thereto.

After the internal electrode 13 and the heating member 14 are formed, the masks M1 and M2 may be removed. In addition, surface processing may be performed. The surface processing may include, for example, a polishing using a grinder or the like. Through this, the shapes of the internal electrode 13 and the heating member 14 may be processed to adjust the resistance values and sizes thereof. After the process of forming the internal electrode 13 and the heating member 14, a cleaning process and a drying process may be performed. For example, the cleaning process may be performed by a method such as ultrasonic cleaning. For example, the drying process may be performed by exposing the electrostatic chuck 10 (e.g., the core member 12a, inner body 12b, internal electrode 13, and/or the heating member 14) to a temperature (environment) higher than the room temperature. For example, the drying process may be performed by exposing the electrostatic chuck 10 (e.g., the core member 12a, inner body 12b, internal electrode 13, and/or the heating member 14) to an environment of 100° C. to 110° C. for 50 minutes to 70 minutes.

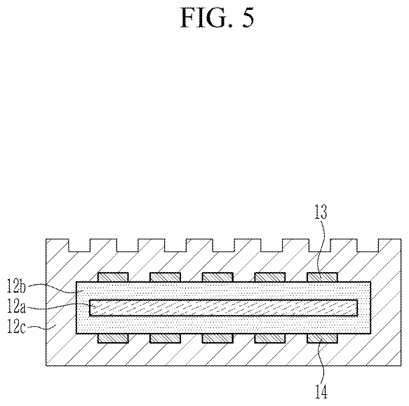

Referring to FIG. 5, the outer body 12c may be formed on the inner body 12b, the internal electrode 13, and the heating member 14. The outer body 12c may be formed through a deposition process. Material of the outer body 12c may include, for example, pBN. Deposition of the outer body 12c may be performed by chemical vapor deposition (CVD) using a boron precursor. The deposition process may be performed in a process environment in which carbon components are removed. Boron may have a similar lattice constant to that of the internal electrode 13 and the heating member 14, which include graphite. Accordingly, boron crystals may stably grow on an outer surface of the internal electrode 13 and the heating member 14. The outer body 12c may be formed to have a thickness by which the internal electrode 13 and the heating member 14 may be shielded from the outside. For example, the outer body 12c may cover the internal electrode 13 and the heating member 14. After the process of forming the outer body 12c, a cleaning process and a drying process may be performed. The cleaning process may be performed by a method such as ultrasonic cleaning. The drying process may be performed by exposing the electrostatic chuck 10 (e.g., the core member 12a, inner body 120b, internal electrode 13, the heating member 14, and/or outer body 12c) to a temperature environment higher than the room temperature. For example, the drying process may be performed by exposing the electrostatic chuck 10 (e.g., the core member 12a, inner body 120b, internal electrode 13, the heating member 14, and/or outer body 12c) to an environment of 100° C. to 110° C. for 50 minutes to 70 minutes.

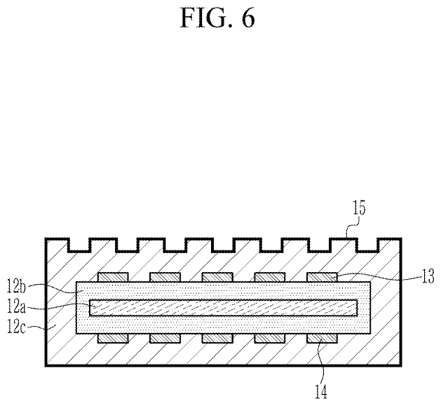

Referring to FIG. 6, the coating layer 15 may be formed on the outer surface of the body 12 (e.g., a surface of the outer body 12c). For example, the coating layer 15 may be formed by a deposition process using a silicon precursor. For example, the coating layer 15 may be formed by chemical vapor deposition (CVD) using a silicon precursor. An additional reaction material together with silicon precursor may be supplied to deposition environment of the coating layer 15. In some embodiments, the additional reaction material may include at least one element selected from among nitrogen, oxygen, and carbon. For example, nitrogen may be supplied in the form of nitrogen gas. Oxygen may be supplied in the form of oxygen gas or ozone. Carbon may be supplied using an inert gas as a medium gas. An inert gas may be additionally supplied to the deposition environment.

Silicon provided by the silicon precursor may be coated in the form of a silicon-containing material on the outer surface of the body 12 (e.g., a surface of the outer body 12c), to form the coating layer 15. At this time, silicon-containing material may be silicon, or a silicon compound. The silicon compound may be a compound of silicon and at least one element selected from among nitrogen, oxygen, and carbon.

Silicon provided by silicon precursor may react with the additional reaction material, and then may be coated in the form of silicon-containing material on the outer surface of the body 12, to form the coating layer 15. At this time, the silicon-containing material may be a silicon compound obtained by reacting silicon with at least one element selected from among nitrogen, oxygen, and carbon. That is, the silicon-containing material may include, for example, silicon oxide, silicon nitride, and silicon carbide. In some embodiments, the silicon-containing material may be a silicon compound including silicon and at least one element selected from among nitrogen, oxygen, carbon. For example, the silicon-containing material may include silicon nitride (SxNy), silicon oxynitride (SiNxOy), silica (SiO₂), silicon oxycarbide (SiOxCy), silicon oxycarbonitride (SiOCN), silicon carbide (SiC), or the like.

A film forming material forming the coating layer 15 may have a content of silicon-containing material of 90% or more. The film forming material forming the coating layer 15 may have a content of silicon-containing material of one type of 90% or more. In some embodiments, the film forming material forming the coating layer 15 may have a content of silicon-containing material of one type of 99% or more. That is, it may be understood that the coating layer 15 may be formed by substantially one (one type of) silicon-containing material. Accordingly, the coating layer 15 may have a stable crystal structure over the entire region. Herein, one type may refer to a single type, a single kind, a single structure, and/or a single crystal system.

In some embodiments, the coating layer 15 may be formed by atomic layer deposition (ALD) using a silicon precursor. An additional reaction material and an inert gas may be supplied to deposition environment, the same as or similarly to chemical vapor deposition (CVD). The coating layer 15 may be formed as a thin film in atomic layer units.

In some embodiments, the coating layer 15 may be formed by plasma-enhanced atomic layer deposition using a silicon precursor. An additional reaction material and an inert gas may be supplied to deposition environment, the same as or similarly to chemical vapor deposition (CVD). The coating layer 15 may be formed as a thin film in atomic layer units.

In addition, the coating layer 15 may be formed by atmospheric plasma spray.

When the coating layer 15 is formed of the silicon-containing material including silicon nitride, the coefficient of thermal expansion of the coating layer 15 may be highly similar to the coefficient of thermal expansion of the outer region of the body 12 (e.g., the outer body 12c) that includes pBN. Accordingly, the bonding state of the body 12 and the coating layer 15 may be thermally stabilized.

Silicon nitride may have high (higher) hardness, density, flexural strength, and bulk modulus of elasticity (than pBN). Accordingly, when the silicon-containing material includes silicon nitride, physical characteristics of the electrostatic chuck 10 may be improved.

Silicon nitride may have a high (higher) thermal conductivity (than pBN). Accordingly, when the silicon-containing material includes silicon nitride, heat transfer efficiency between the electrostatic chuck 10 and the substrate may be improved.

Silicon nitride may have a high (higher) volume resistivity (than pBN). Accordingly, when the silicon-containing material includes silicon nitride, the electrostatic chuck 10 may be stably used in an ion implantation process and a plasma process for the substrate.

Silicon nitride may have the same crystal structure as pBN. Accordingly, when the silicon-containing material includes silicon nitride, the coating layer 15 may be more stably bonded to the outer surface of the body 12.

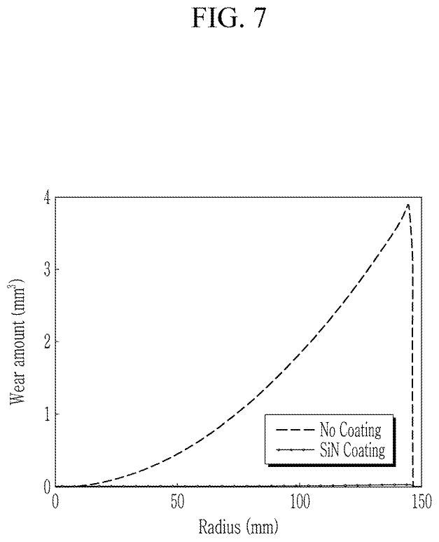

FIG. 7 is a simulation result of wear characteristics.

Simulations were performed for each of an electrostatic chuck without a coating layer and an electrostatic chuck (e.g., the electrostatic chuck 10) with the coating layer 15, including silicon nitride. The simulation was performed using the Archard equation of Equation 1.

$$Q = \frac{KWL}{H} \qquad ( Equation 1 )$$

Q is the total amount of wear debris generated (e.g., particles generated by the wear of the electrostatic chuck), K is a dimensionless constant, W is the total normal load, L is the sliding distance, and H is the hardness of the smoothest contacting surface (between the electrostatic chuck and the adsorbed substrate).

The simulation was performed assuming that the adsorbed substrate is a silicon wafer, the chucking force is 1000 N, the friction coefficient is 0.8, K=1, the temperature of the electrostatic chuck is 400° C., the initial temperature of the substrate (e.g., wafer) is 23° C., and the thickness of the coating layer 15 is 1 mm.

Simulation results of the amount of wear along the radial direction of an electrostatic chuck without a coating layer as well as an electrostatic chuck with the coating layer 15, including silicon nitride, are shown in FIG. 7. Referring to FIG. 7, in the case of an electrostatic chuck without a coating layer, the amount of wear caused by friction (between the electrostatic chuck and the substrate) greatly increases toward the outer region (e.g., an outer region of the electrostatic chuck and/or an outer region of the substrate). On the other hand, the amount of wear of the electrostatic chuck (e.g., the electrostatic chuck 10) on which the coating layer 15 is formed is greatly reduced. Particularly, it may be seen that the amount of wear of the electrostatic chuck 10 on which the coating layer 15 is formed is extremely low even in the outer region (e.g., an outer region of the electrostatic chuck 10 and/or an outer region of the substrate), similar to that in the central region (e.g., a center region of the electrostatic chuck 10 and/or a center region of the substrate).

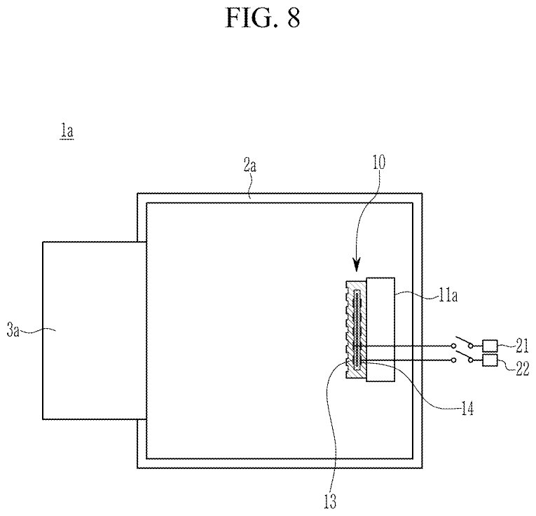

FIG. 8 is a drawing showing a substrate processing apparatus including an electrostatic chuck of FIG. 1 according to some embodiments.

Referring to FIG. 8, a substrate processing apparatus 1a may include a chamber 2a, an ion supply source 3a, the electrostatic chuck 10 and a supporting member 11a.

The substrate processing apparatus 1a may perform an ion implantation process on the substrate.

The chamber 2a may provide a process space (a process environment) in which a substrate processing process (e.g., the ion implantation process) is performed. The chamber 2a may be provided in a closed shape (e.g., at least a partially closed shape and/or a closable shape).

The ion supply source 3a may be connected to a first side of the chamber 2a. The ion supply source 3a may supply ions to the process space of the chamber 2a.

The electrostatic chuck 10 may be positioned inside the chamber 2a. The electrostatic chuck 10 may adsorb the substrate on an upper surface thereof. The upper surface of the electrostatic chuck 10 may be positioned to face the ion supply source 3a. The electrostatic chuck 10 may be positioned to be inclined with respect to a horizontal plane. For example, the ion supply source 3a may extend in parallel with the horizontal plane. The internal electrode 13 of the electrostatic chuck 10 may be electrically connected to an adsorption power source 21. The adsorption power source 21 may include a DC power supply. An electrostatic force may occur between the internal electrode 13 and the substrate by the voltage applied by the adsorption power source 21, and the electrostatic force may cause the substrate to be adsorbed to the electrostatic chuck 10.

The heating member 14 of the electrostatic chuck 10 may be electrically connected to a heating power source 22. The heating member 14 may be resistively heated by the power supplied by the heating power source 22. Accordingly, the substrate adsorbed by the electrostatic chuck 10 and the electrostatic chuck 10 may be heated (by the heating member 14).

The supporting member 11a may be connected to a lower portion (e.g., a lower surface) of the electrostatic chuck 10, to (physically) support the electrostatic chuck 10. The supporting member 11a may be provided as a movable structure, such that the position of the electrostatic chuck 10 may be changed.

In the process of using the substrate processing apparatus 1a, wear of the coating layer 15 may occur. When the coating layer 15 includes silicon or a silicon compound, particles generated by wear of the coating layer 15 may include silicon. Silicon may react with fluorine as shown in Chemical Formula 1 below, to become silicon tetrafluoride gas. Silicon tetrafluoride gas may be removed through discharging of interior gas of the substrate processing apparatus 1a (e.g., the chamber 2a). Accordingly, by supplying the fluorine-based gas, by reacting the supplied gas with the particles generated by the wear of the coating layer 15, and then by exhausting the internal gas, the in situ dry-cleaning process may be performed in the substrate processing apparatus 1a (e.g., in the chamber 2a).

Si+F₄→SiF₄(g) (Chemical Formula 1)

In addition, when the coating layer 15 includes silicon nitride, nitrogen may react with fluorine as shown in Chemical Formula 2 below, to become nitrogen trifluoride gas. Accordingly, the substrate processing apparatus 1a may effectively remove particles generated by the wear of the coating layer 15 through in situ dry-cleaning process by using fluorine-based gas.

N+F₃→NF₃(g) (Chemical Formula 2)

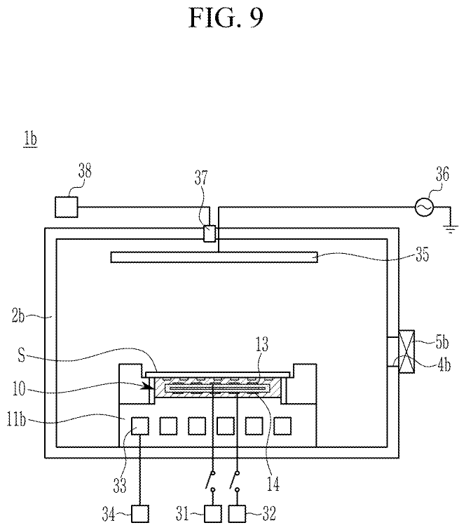

FIG. 9 is a drawing showing a substrate processing apparatus including an electrostatic chuck of FIG. 1 according to some embodiments.

Referring to FIG. 9, a substrate processing apparatus 1b may include a chamber 2b, the electrostatic chuck 10, a supporting member 11b and a plasma excitation member 35.

The substrate processing apparatus 1b may process a substrate S using plasma. For example, the substrate processing apparatus 1b may perform an etching process, a deposition process, an ashing process, and the like with respect to the substrate S by using the excited plasma.

The chamber 2b may provide a process space (e.g., a process environment) in which a substrate processing process (e.g., a plasma process) is performed. The chamber 2b may be provided in a closed shape (e.g., at least a partially closed shape and/or a closable shape). An opening 4b may be formed at a first side of the chamber 2b. The opening 4b may be provided as a path through which the substrate S is carried into or taken out from the chamber 2b. The opening 4b may be opened and closed by a door 5b.

The electrostatic chuck 10 may be positioned inside the chamber 2b. The electrostatic chuck 10 may adsorb the substrate S on an upper surface thereof. The internal electrode 13 of the electrostatic chuck 10 may be electrically connected to an adsorption power source 31. The adsorption power source 31 may include a DC power supply. An electrostatic force may occur between the internal electrode 13 and the substrate S by the voltage applied by the adsorption power source 31, and the electrostatic force may cause the substrate S to be adsorbed to the electrostatic chuck 10. The heating member 14 of the electrostatic chuck 10 may be electrically connected to a heating power source 32. The heating member 14 may be resistively heated by the power supplied by the heating power source 32. Accordingly, the substrate S adsorbed by the electrostatic chuck 10 and the electrostatic chuck 10 may be heated by the heating member 14.

The supporting member 11b may be connected to the lower portion (e.g., a lower surface) of the electrostatic chuck 10, to (physically) support the electrostatic chuck 10. A refrigerant fluid line 33 may be formed inside the supporting member 11b. The refrigerant fluid line 33 may be connected to a refrigerant storage portion 34. The refrigerant storage portion 34 may supply the refrigerant through the refrigerant fluid line 33. The supporting member 11b may include a conductive material. For example, at least a portion of the supporting member 11b may be made of a conductive material.

The plasma excitation member 35 may provide energy for excitation of plasma to the inside of the chamber 2b. The plasma excitation member 35 may be positioned above (on) the process space of the chamber 2b. For example, the plasma excitation member 35 may be inside the chamber 2b. The plasma excitation member 35 may be in an upper portion of the process space of the chamber 2b. The plasma excitation member 35 may include a conductive material and have a predetermined area (size). The plasma excitation member 35 may be positioned to face the supporting member 11b.

A high frequency power supply 36 may be provided to generate high frequency power. The high frequency power supply 36 may be connected to at least one of the plasma excitation member 35 and the supporting member 11b. Accordingly, electric field may be formed by the power provided by the high frequency power supply 36 in a space between the plasma excitation member 35 and the supporting member 11b, such that a process gas may be excited into a plasma state.

The gas supply member 38 may supply the process gas into the chamber 2b. The gas supply member 38 may be connected to a gas inlet 37 that is positioned on a second side of the chamber 2b. The gas inlet 37 may be positioned on an upper portion (e.g., upper surface) of the chamber 2b.

In addition, by the substrate processing apparatus 1b, as described in connection with the substrate processing apparatus 1a of FIG. 8, particles generated by the wear of the coating layer 15 may be effectively removed through in situ dry-cleaning process by using fluorine-based gas.

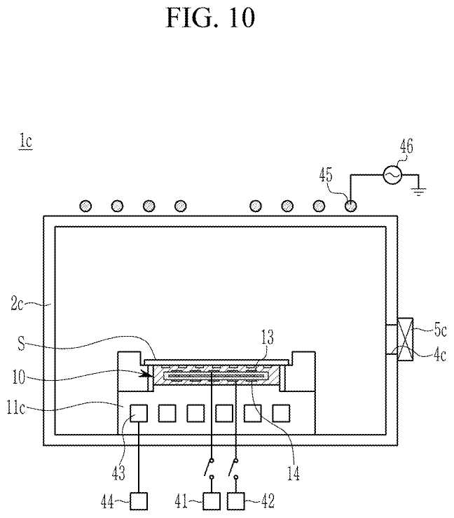

FIG. 10 is a drawing showing a substrate processing apparatus including an electrostatic chuck of FIG. 1 according to some embodiments.

Referring to FIG. 10, a substrate processing apparatus 1c may include a chamber 2c, the electrostatic chuck 10, a supporting member 11c and a plasma excitation member 45.

The substrate processing apparatus 1c may process the substrate S by using plasma. For example, the substrate processing apparatus 1c may perform an etching process, a deposition process, an ashing process, and the like with respect to the substrate S by using the excited plasma.

The chamber 2c may provide a process space (e.g., a process environment) in which a substrate processing process (e.g., a plasma process) is performed. The chamber 2c may be provided in a closed shape (e.g., at least a partially closed shape and/or a closable shape). An opening 4c may be formed at a first side of the chamber 2c. The opening 4c may be provided as a path through which the substrate S is carried into or taken out from the chamber 2c. The opening 4c may be opened and closed by a door 5c.

The electrostatic chuck 10 may be positioned inside the chamber 2c. Since the connection structure and function of an adsorption power source 41 and a heating power source 42 are the same as or similar to those of the adsorption power source 31 and the heating power source 32 of FIG. 9, duplicated descriptions may be omitted.

The supporting member 11c may be connected to the lower portion (e.g., the lower surface) of the electrostatic chuck 10, to (physically) support the electrostatic chuck 10. A refrigerant fluid line 43 may be formed inside the supporting member 11c. The refrigerant fluid line 43 may be connected to a refrigerant storage portion 44. The refrigerant storage portion 44 may supply the refrigerant through the refrigerant fluid line 43.

The plasma excitation member 45 may provide energy for excitation of plasma to the inside of the chamber 2c. The plasma excitation member 45 may be positioned outside (the process space) of the chamber 2c. For example, the plasma excitation member 45 may be positioned on an outer surface (e.g., an upper surface) of the chamber 2c. The plasma excitation member 45 may be positioned to face the process space of the chamber 2c. For example, the plasma excitation member 45 may face the upper surface of the chamber 2c. The plasma excitation member 45 may be provided as antenna. A high frequency power supply 46 may be provided to generate high frequency power. The high frequency power supply 46 may be connected to the plasma excitation member 45. Accordingly, the electromagnetic field generated by the plasma excitation member 45 by the power provided by the high frequency power supply 46 may excite the gas of the process space of the chamber 2c into plasma.

In addition, by the substrate processing apparatus 1c, as described in connection with the substrate processing apparatus 1a of FIG. 8, particles generated by the wear of the coating layer 15 may be effectively removed through in situ dry-cleaning process by using fluorine-based gas.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the scope of the present invention. It therefore will be understood that the embodiments described above are just illustrative but not limitative in all aspects.

What is claimed is:

1. An electrostatic chuck, comprising:
a body;
an internal electrode in the body, wherein the internal electrode is configured to generate an electrostatic force when a voltage is applied to the internal electrode; and
a coating layer on an outer surface of the body,
wherein the coating layer is formed of a film forming material including a silicon-containing material.

2. The electrostatic chuck of claim 1, wherein the silicon-containing material is silicon.

3. The electrostatic chuck of claim 1, wherein the silicon-containing material includes a silicon compound.

4. The electrostatic chuck of claim 3, wherein the silicon compound includes silicon and at least one element among nitrogen, oxygen, and carbon.

5. The electrostatic chuck of claim 1, wherein the film forming material has a content of the silicon-containing material of 90% or more.

6. The electrostatic chuck of claim 1, wherein the film forming material has a content of the silicon-containing material of one type of 90% or more.

7. The electrostatic chuck of claim 1, wherein a first coefficient of thermal expansion of the coating layer is 50% of a lower limit value to 150% of an upper limit value of a second coefficient of thermal expansion of the outer surface of the body.

8. The electrostatic chuck of claim 1, wherein the coating layer has a first coefficient of thermal expansion of 1 (10⁻⁶/K) to 4 (10⁻⁶/K).

9. The electrostatic chuck of claim 1, wherein the coating layer has a thickness of 1 μm to 2 mm.

10. The electrostatic chuck of claim 1, wherein the coating layer has a thickness of 10 μm to 200 μm.

11. The electrostatic chuck of claim 1, wherein an outer region of the body includes pyrolytic boron nitride (pBN).

12. The electrostatic chuck of claim 11, wherein the silicon-containing material includes silicon nitride.

13. The electrostatic chuck of claim 1, wherein the body comprises:
an outer body;
an inner body in the outer body; and
a core member in the inner body.

14. An electrostatic chuck, comprising:
a body;
an internal electrode in the body, wherein the internal electrode is configured to generate an electrostatic force when a first voltage is applied to the internal electrode;
a heating member in the body, wherein the heating member is configured to generate heat through resistance heating when a second voltage is applied to the heating member; and
a coating layer on an outer surface of the body,
wherein an outer region of the body includes pyrolytic boron nitride (pBN),
wherein the coating layer comprises a film forming material that includes a silicon-containing material, wherein the silicon-containing material has a coefficient of thermal expansion of 1 (10⁻⁶/K) to 4 (10⁻⁶/K).

15. The electrostatic chuck of claim 14, wherein the film forming material has a content of the silicon-containing material of 90%, and
wherein the silicon-containing material is silicon nitride.

16. A substrate processing apparatus, comprising:
a chamber; and
an electrostatic chuck in the chamber, wherein the electrostatic chuck is configured to adsorb a substrate,
the electrostatic chuck comprises:
a body;
an internal electrode in the body, wherein the internal electrode is configured to generate an electrostatic force when a first voltage is applied to the internal electrode;
a heating member in the body, wherein the heating member is configured to generate heat through resistance heating when a second voltage is applied to the heating member; and
a coating layer on an outer surface of the body,
wherein an outer region of the body includes pyrolytic boron nitride,
wherein the coating layer comprises a film forming material that includes a silicon-containing material, and
wherein the silicon-containing material has a coefficient of thermal expansion of 1 (10⁻⁶/K) to 4 (10⁻⁶/K).

17. The substrate processing apparatus of claim 16, further comprising an ion supply source connected to a first side of the chamber, wherein the ion supply source is configured to supply ions to a process space in the chamber.

18. The substrate processing apparatus of claim 16, further comprising a plasma excitation member in the chamber,
wherein the plasma excitation member is in an upper portion of a process space that is in the chamber, and
wherein the plasma excitation member includes a conductive material.

19. The substrate processing apparatus of claim 16, further comprising an antenna on an outer surface of the chamber.

20. The substrate processing apparatus of claim 16, wherein the silicon-containing material is silicon nitride.
